(19) United States
(12) Patent Application Publication
(10) Pub. No.: US 2010/0294344 A1
(43) Pub. Date: Nov. 25, 2010

(54) DECORATION FILM AND DECORATION DEVICE

(75) Inventor: Shih-Min Huang, Taipei City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: SIPIX CHEMICAL INC., Taoyuan County (TW)

(21) Appl. No.: 12/851,543

(22) Filed: Aug. 5, 2010

Related U.S. Application Data
(63) Continuation-in-part of application No. 11/513,333, filed on Aug. 29, 2006.
(60) Provisional application No. 60/721,861, filed on Sep. 28, 2005.

(51) Int. Cl. H01L 31/0203; H01L 31/0232

(52) U.S. Cl. 136/251; 136/256; 977/742; 977/932

(57) ABSTRACT

A decoration film is provided. The decoration film includes a flexible substrate, a first electrode layer disposed on the flexible substrate, a polymer photoelectric conversion layer disposed on the first electrode layer, a second electrode layer disposed on the polymer photoelectric conversion layer, and an adhesion layer disposed on the second electrode layer. The polymer photoelectric conversion layer is located between the first electrode layer and the second electrode layer. At least one of the first electrode layer and the second electrode layer is a transparent conductive layer. The first electrode layer, the polymer photoelectric conversion layer, and the second electrode layer are located between the adhesion layer and the flexible substrate.

### CROSS-REFERENCE TO RELATED APPLICATION

This is a continuation-in-part application of and claims priority benefit of patent application Ser. No. 11/513,333, filed on Aug. 29, 2006, which claims the priority benefit of U.S. provisional application No. 60/721,861 filed on Sep. 28, 2005. The entirety of each of the above-mentioned patent applications is hereby incorporated by reference herein and made a part of this specification.

### BACKGROUND OF THE INVENTION

1. Field of the Invention

The present invention generally relates to a decoration film and a decoration device, in particular, to a decoration film and a decoration device having photoelectric conversion function.

2. Description of Related Art

Conventionally, the illustrations, or the decorations formed on the surface of the plastic housing are mainly fabricated by spraying process or printing process to present certain effect on the sense of sight. Nevertheless, the spraying process is unfavorable in mass production for the disadvantages of time consumption, process complexity, and inconsistence in thickness. In addition, the conventional spraying process may cause the splashing of sprays containing lead or other heavy metals so that the spraying material is wasted and the problem of pollution is caused.

To solve the abovementioned problem, an in-mold decoration (IMD) technique is provided. The process of the IMD technique includes placing a decoration film that has the predetermined decorations or patterns into the mold of the injection machine, injecting a melted resin at a side of the film in the mold so that the melted resin and the film are combined, and thereafter ejecting the decorated housing from the mold. Accordingly, a decoration device is completed.

Accompanying with the rapid development of the information products, the application of the decoration device is gradually extended. In addition to provide the visual decoration effect, the decoration device is further requested to have more functions such as an anti-dirt function, a rough touch sensation, or the like. Therefore, the decoration film needs further improvement.

### SUMMARY OF THE INVENTION

Accordingly, the invention is directed to a decoration film capable of providing a photoelectric conversion function.

The present invention is directed to a decoration device having a polymer photoelectric conversion layer so as to provide the photoelectric conversion function.

According to an embodiment of the invention, a decoration film is provided. The decoration film includes a flexible substrate, a first electrode layer disposed on the flexible substrate, a polymer photoelectric conversion layer disposed on the first electrode layer, a second electrode layer disposed on the polymer photoelectric conversion layer, and an adhesion layer disposed on the second electrode layer. The polymer photoelectric conversion layer is located between the first electrode layer and the second electrode layer. At least one of the first electrode layer and the second electrode layer is a transparent conductive layer. The first electrode layer, the polymer photoelectric conversion layer, and the second electrode layer are located between the adhesion layer and the flexible substrate.

According to an embodiment of the invention, a material of the polymer photoelectric conversion layer includes a p-type semiconductor polymer and an n-type semiconductor polymer. Specifically, the p-type semiconductor polymer includes at least one of polythiophene, polyfluorene, polyphenylenevinylene, a derivative of polythiophene, a derivative of polyfluorene, a derivative of polyphenylenevinylene, poly(3-hexylthiophene) (P3HT), a conjugated oligomer, and a small molecule, wherein the derivative of polythiophene includes, for example, at least one of poly(dioctyfluorene), poly[2-methoxy-5-(2-ethyl-hexyloxy)-1,4-phenylene vinylene, and a combination thereof. In addition, the conjugated oligomer can be sexithiophene and the small molecule includes at least one of pentacene, tetracene, hexabenzcoronene, phthalocyanine, porphyrines, a derivative of pentacene, a derivative of tetracene, a derivative of hexabenzcoronene, a derivative of phthalocyanine, a derivative of porphyrines, and a combination thereof. Alternatly, the n-type semiconductor polymer includes at least one of C60, a derivative of C60, C70, a derivative of C70, carbon nanotubes, a derivative of carbon nanotubes, 3,4,9,10-perylene tetracarboxylic-bis-benzimidazole (PTCBI), N,N′-dimethyl-3,4,9,10-perylenetetracarboxylic acid diimide (Me-PTCDI), a derivative of PTCBI, a derivative of Me-PTCBI, a poly(2,5,2′ ,5 ′-tetrahexyloxy-7,8 ′-dicyano-di-p-phenylenevinylene (CN-PPV), poly(9,9′-dioctylifluorene-co-benzothiadiazole (F8BT), and a semiconductor nano particle. In an embodiment, the derivative of C60 is phenyl C61-butyric acid methyl ester (PCBM). The carbon nanotubes can include at least one of single wall carbon nanotubes, multi wall carbon nanotubes, and a combination thereof. For example, the semiconductor nano particles include, for instance, at least one of TiO2 nano particles, CdSe nano particles, CdS nano particles, and a combination thereof.

According to an embodiment of the invention, the decoration film further includes a first conductive pattern and a second conductive layer penetrating through the adhesion layer, wherein the first conductive pattern contacts a side of the first electrode layer and the second conductive pattern contacts a side of the second electrode layer away from the flexible substrate.

According to an embodiment of the invention, the decoration film further includes a pattern layer disposed between the flexible substrate and the adhesion layer and located at a side of the polymer photoelectric conversion layer adjacent to the transparent conductive layer.

According to an embodiment of the invention, the decoration film further includes a releasing layer disposed between the flexible substrate and the first electrode layer. Specifically, the decoration film further includes a protection layer disposed between the releasing layer and the first electrode layer. At least one of the releasing layer and the decoration layer has a rough surface away from the first electrode layer, for instance. Furthermore, the decoration film can optionally further includes a first conductive pattern and a second conductive pattern respectively penetrating through the releasing layer, wherein the first conductive pattern and the second conductive pattern respectively contact a side of the first electrode layer away from the adhesion layer and a side of the second electrode layer away from the adhesion layer. In one embodiment, the second conductive pattern can further penetrate through the first electrode layer and the polymer photoelectric conversion layer while the second conductive pattern is electrically isolated from the first electrode layer.

According to an embodiment of the invention, a decoration device is further provided. The decoration device includes a body, an outer layer, a first electrode layer, a polymer photoelectric conversion layer, a second electrode layer, and an adhesion layer. The outer layer is conformally disposed on the body. The first electrode layer is conformally disposed between the body and the outer layer. The polymer photoelectric conversion layer is conformally disposed between the body and the first electrode layer. The second electrode layer is conformally disposed between the polymer photoelectric conversion layer and the body, wherein at least one of the first electrode layer and the second electrode layer is a transparent conductive layer. The adhesion layer is disposed between the second electrode layer and the body.

According to an embodiment of the invention, the decoration device further includes a first conductive pattern and a second conductive pattern penetrating through the adhesion layer, wherein the first conductive pattern contacts a side of the first electrode layer away from the outer layer and the second conductive pattern contacts a side of the second electrode layer away from the outer layer. The first conductive pattern and the second conductive pattern can further penetrate through the body and are exposed at a side of the body away from the outer layer.

According to am embodiment of the invention, the outer layer can be at least one of a flexible substrate, a releasing layer, and a protection layer.

According to an embodiment of the invention, the decoration device can further includes a pattern layer disposed between the outer layer and the adhesion layer and located at a side of the polymer photoelectric conversion layer adjacent to the transparent conductive layer.

According to an embodiment of the invention, the decoration device further includes a first conductive pattern and a second conductive pattern penetrating through the outer layer, wherein the first conductive pattern contacts a side of the first electrode layer away from the adhesion layer and the second conductive pattern contacts a side of the second electrode layer away from the adhesion layer. Specifically, the second conductive pattern can further penetrate through the first electrode layer and the polymer photoelectric conversion layer while the second conductive pattern is electrically isolated from the first electrode layer.

According to an embodiment of the invention, the decoration device can be a housing of an electric device. For example, the electric device can include at least one of a cell phone, a digital camera, a note book, a digital photo frame, a display, a personal digital assistant, a media player, and a global positioning system.

In light of the foregoing, the decoration film and the decoration according to the invention has two electrode layers and a polymer photoelectric conversion layer disposed therebetween, wherein at least one of the two electrode layers is a transparent conductive layer. Therefore, the decoration film and the decoration device is capable of providing photoelectric conversion function. When the decoration film or the decoration device is connected to am electrical storage element, the decoration film or the decoration device can be served as a solar cell so as to provide electrical energy and achieve power saving function.

In order to make the aforementioned and other features and advantages of the invention more comprehensible, embodiments accompanying figures are described in detail below.

Herein, the same or similar reference numbers used in the drawings and the descriptions are referred as the same or similar elements. For clearly describing the concept of the invention, the shapes and the thickness of the elements in the embodiments accompanying with the drawings may not definitely comply with the real circumstance. In addition, the following descriptions are directed to the elements or the combinations thereof, but the elements are not particularly restricted in the contents or the descriptions. Any form or shape known by one skilled in the art is applicable in the invention. Moreover, the description that a material layer disposed on a substrate or disposed on another material layer means that the material layer is directly located on the substrate or the another material layer, and may also mean that some interlayer is interrupted between the material layer and the substrate or between the material layer and the another material layer.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 illustrates a decoration film according to a first embodiment of the invention.

FIG. 2 illustrates a decoration film according to a second embodiment of the invention.

FIG. 3 illustrates a decoration film according to a third embodiment of the invention.

FIG. 4 illustrates a decoration film according to a fourth embodiment of the invention.

FIG. 5 illustrates a decoration device according to an embodiment of the invention.

FIG. 6 illustrates a decoration film according to a fifth embodiment of the invention.

FIG. 7 illustrates a decoration film according to a sixth embodiment of the invention.

FIG. 8 illustrates a decoration device according to another embodiment of the invention.

### DESCRIPTION OF THE EMBODIMENTS

Reference will now be made in detail to the present embodiments of the invention, examples of which are illustrated in the accompanying drawings. Wherever possible, the same reference numbers are used in the drawings and the description to refer to the same or like parts.

For achieving a photoelectric conversion effect of a product, the following descriptions exemplified depict a decoration device and a decoration film. Several decoration processes such as an in-mold decoration (IMD) technique, a heat transfer printing process, a sublimation heat transfer process, a hot stamping process, an ink jet printing process, a water transfer printing process, and the like are provided for forming a decoration device, wherein the IMD technique substantially includes an in-mold labelling (IML) process, an in-mold film (IMF) process, an in-mold roller (IMR) process, or the like. It is noted that the decoration film described hereinafter can be applied in any of the aforesaid decoration processes, but the invention is not limited thereto. For example, the decoration film can be adhered on any object for providing the photoelectric conversion function without adopting the IMD technique.

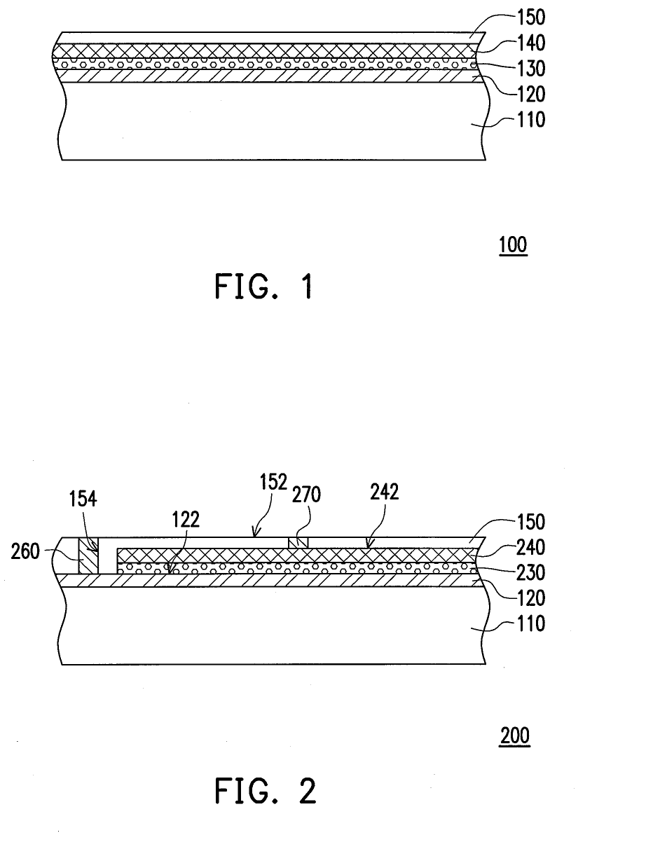

FIG. 1 illustrates a decoration film according to a first embodiment of the invention. Referring to FIG. 1, a decoration film 100 includes a flexible substrate 110, a first electrode layer 120 disposed on the flexible substrate 110, a polymer photoelectric conversion layer 130 disposed on the first electrode layer 120, a second electrode layer 140 disposed on the polymer photoelectric conversion layer 130, and an adhesion layer 150 disposed on the second electrode layer 140. Specifically, the first electrode layer 120, the polymer photoelectric conversion layer 130, and the second electrode layer 140 are located between the adhesion layer 150 and the flexible substrate 110. Furthermore, the adhesion layer 150 substantially completely covers over the first electrode layer 120, the polymer photoelectric conversion layer 130, and the second electrode layer 140.

A material of the flexible substrate 110 can be polyethylene terephthalate (PET), polyethylene naphthalate (PEN), polyethylene glycol-co-cyclohexane-1,4 dimethanol terephthalate (PETG), thermalplastic polyurethane (TPU), polyurethane (PU), polypropylene (PP), polycarbonate (PC), amorphous polyethylene terephthalate (A-PET), polyvinyl chloride (PVC), Polystyrene (PS), triacetyl cellulose (TAC), polymethylmethacrylate (PMMA), methylmethacrylate-styrene (MMA-st, MS) copolymer,cyclo olefin copolymer (COC) and a combination thereof, but the invention is not restricted herein.

The first electrode layer 120 and the second electrode layer 140 can be made of the conductive materials selected from Sn, Cr, Ti, Ni, Zn, Mo Al, Au, Ag, Cu, ITO, IZO, ZnO, or a combination thereof. Nevertheless, at least one of the first electrode layer 120 and the second electrode layer 140 is made of a transparent conductive material such as ITO, IZO, ZnO, or the like according to the present embodiment. That is to say, at least one of the first electrode layer 120 and the second electrode layer 140 according to the present embodiment is a transparent conductive layer.

The adhesion layer 150 may be formed from a material such as polyacrylate, polymethacrylate, polystyrene, polycarbonate, polyurethane, polyester, polyamide, epoxy resin, ethylene vinylacetate copolymers (EVA), thermoplastic elastomers or the like, or copolymers, blends or composites thereof. Hot melt or heat activated adhesions such as polyurethane and polyamide are particularly preferred. In addition to the materials indicated above, a composition suitable for an adhesion layer is disclosed in U.S. 2006/0019088, the content of which is incorporated herein by reference in its entirety. Briefly, the adhesion layer composition may comprise an adhesion binder and a polymeric particulate material.

In addition, a material of the polymer photoelectric conversion layer 130 includes a p-type semiconductor polymer and an n-type semiconductor polymer. Specifically, the p-type semiconductor polymer includes at least one of polythiophene, polyfluorene, polyphenylenevinylene, a derivative of polythiophene, a derivative of polyfluorene, a derivative of polyphenylenevinylene, poly(3-hexylthiophene) (P3HT), a conjugated oligomer, and a small molecule, wherein the derivative of polythiophene includes, for example, at least one of poly(dioctyfluorene), poly[2-methoxy-5-(2-ethyl-hexyloxy)-1,4-phenylene vinylene, and a combination thereof. In addition, the conjugated oligomer can be sexithiophene and the small molecule includes at least one of pentacene, tetracene, hexabenzcoronene, phthalocyanine, porphyrines, a derivative of pentacene, a derivative of tetracene, a derivative of hexabenzcoronene, a derivative of phthalocyanine, a derivative of porphyrines, and a combination thereof Alternatly, the n-type semiconductor polymer includes at least one of C60, a derivative of C60, C70, a derivative of C70, carbon nanotubes, a derivative of carbon nanotubes, 3,4,9,10-perylene tetracarboxylic-bis-benzimidazole (PTCBI), N,N′-dimethyl-3,4,9,10-perylenetetracarboxylic acid diimide (Me-PTCDI), a derivative of PTCBI, a derivative of Me-PTCBI, a poly(2,5,2′,5 ′-tetrahexyloxy-7,8′-dicyano-di-p-phenylenevinylene (CN-PPV), poly(9,9′-dioctylifluorene-co-benzothiadiazole (F8BT), and a semiconductor nano particle. In an embodiment, the derivative of C60 is phenyl C61-butyric acid methyl ester (PCBM). The carbon nanotubes can include at least one of single wall carbon nanotubes, multi wall carbon nanotubes, and a combination thereof. For example, the semiconductor nano particles include, for instance, at least one of TiO2 nano particles, CdSe nano particles, CdS nano particles, and a combination thereof.

In the present embodiment, the polymer photoelectric conversion layer 130 is located between the first electrode layer 120 and the second electrode layer 140. In addition, at least one of the first electrode layer 120 and the second electrode layer 140 is transparent for allowing an ambient light passing therethrough. Accordingly, the ambient light can pass through the transparent conductive layer (any one of the first electrode layer 120 and the second electrode layer 140) and irradiate on the polymer photoelectric conversion layer 130 so that the polymer photoelectric conversion layer 130 can provide a photoelectric conversion function and convert light energy into electrical energy. Meanwhile, the first electrode layer 120 and the second electrode layer 140 facilitate to transmit electrical energy to-be used for achieving an aspiration of green energy. In another embodiment, an electron transporting layer and a hole transporting layer can be selectively disposed between the first electrode layer 120 and the polymer photoelectric conversion layer 130 and between the second electrode layer 140 and the polymer photoelectric conversion layer 130 to achieve high photoelectric conversion efficiency.

A manufacturing method of the decoration film 100 can usually be sequentially forming the decoration layers having specific function on the flexible substrate 110 through a printing process. Therefore, the first electrode layer 120, the polymer photoelectric conversion layer 130, and the second electrode layer 140 are preferably capable of being formed on the flexible substrate 110 through the printing process. In the present embodiment, the layer for providing the photoelectric conversion function is the polymer photoelectric conversion layer 130 which is compatible to the printing process. Accordingly, the formation of the polymer photoelectric conversion layer 130 does not require other deposition process, which is prevented from the damage causing by other deposition process.

In addition, any of the first electrode layer 120, the polymer photoelectric conversion layer 130, and the second electrode layer 140 can be selectively patterned rather than completely cover the underlying layer according to the design requirement and can be selectively formed by multi layers stacked together. That is to say, the drawing shown in FIG. 1 is exemplarily illustrated but is not intended to limit the amount of the layers and the pattern of the layers in the decoration film 100 of the invention.

Specifically, the flexible substrate 110 provides the flexibility so that the decoration film 100 can be conformed to a surface of an object by adhering the decoration film 100 on the surface through the adhesion layer 150. Therefore, no matter the shape of the object is can the photoelectric conversion function be accomplished by adhering the decoration film 100. For instance, the decoration film 100 can be adhered on a window glass, a wall, a housing of a product, or the like through the adhesion layer 150 to be served as the photoelectric conversion element of a solar cell. Under this circumstance, the flexible substrate 110 is further conducive to protect the first electrode layer 120, the polymer photoelectric conversion layer 130, and the second electrode layer 140 from damage caused by ambient materials such as air, water, etc.

FIG. 2 illustrates a decoration film according to a second embodiment of the invention. Referring to FIG. 2, a decoration film 200 according to the present embodiment is similar to the decoration film 100 illustrated in FIG. 1 and also includes the flexible substrate 110, the first electrode layer 120, the polymer photoelectric conversion layer 230, the second electrode layer 240, and the adhesion layer 150. It is noted that the polymer photoelectric conversion layer 230 and the second electrode layer 240 can be formed by patterning the polymer photoelectric conversion layer 130 and the second electrode layer 140 depicted in FIG. 1. Therefore, the materials and the disposition relationships of the flexible substrate 110, the first electrode layer 120, the polymer photoelectric conversion layer 230, the second electrode layer 240, and the adhesion layer 150 can be referred to the aforesaid embodiment. In addition, the decoration film 200 further includes a first conductive pattern 210 and a second conductive layer 220 for transmitting the electrical energy.

In the present embodiment, the polymer photoelectric conversion layer 230 and the second electrode layer 240 are patterned so as to expose a portion of a side 122 of the first electrode layer 120 away from the flexible substrate 110. The first conductive pattern 210 and the second conductive pattern 220 penetrate through the adhesion layer 150. The manufacturing method of the first conductive pattern 210 and the second conductive pattern 220 can include forming a plurality of through holes 154 in the adhesion layer 150 and filling the through holes 154 with a conductive material. However, the invention is not limited thereto. In an alternative embodiment, the first conductive pattern 260 and the second conductive pattern 270 can be formed by the printing process during the formation of the adhesion layer 150.

The first conductive pattern 210 contacts the exposed portion of the side 122 of the first electrode layer 120. The second conductive pattern 220 contacts a side 242 of the second electrode layer 240 away from the flexible substrate 110. In addition, the first conductive pattern 210 and the second conductive pattern 220 can be exposed at a side 152 of the adhesion layer 150 away from the first electrode layer 120.

When the decoration film 200 is adhered on an object having an electrical storage element, the exposed portion of the first conductive pattern 210 and the exposed portion of the second conductive pattern 220 can be connected to the electrical storage element. The electrical energy generating by the polymer photoelectric conversion layer 230 can be stored, which is served as a solar cell. Accordingly, the green energy design of the object is accomplished.

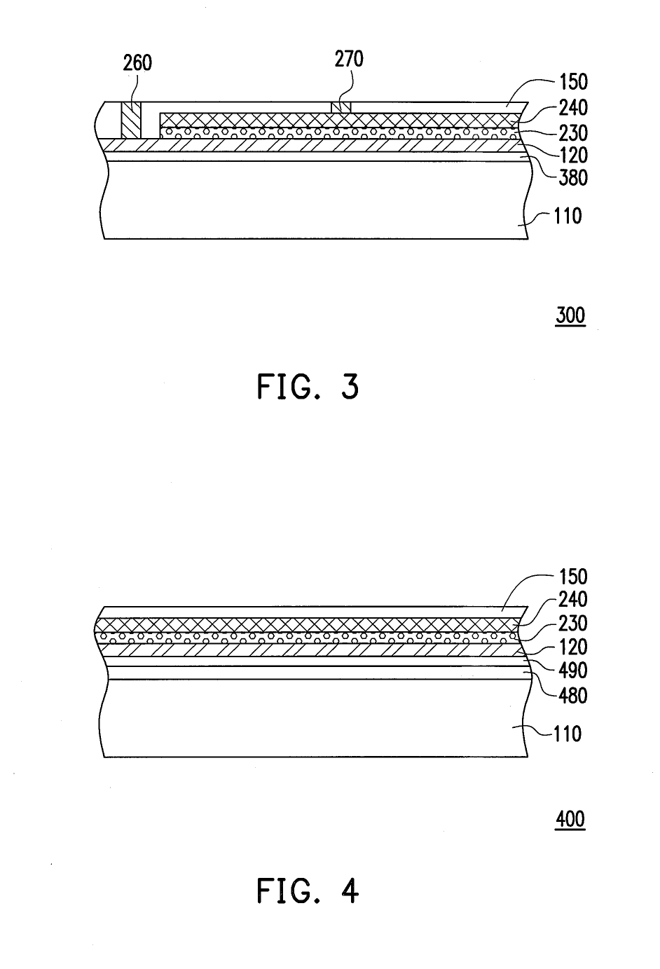

FIG. 3 illustrates a decoration film according to a third embodiment of the invention. Referring to FIG. 3, a decoration film 300 includes the elements of the decoration film 200 as described in the foregoing and further includes a decoration layer 380. Herein, the materials, the disposition relationships, and the patterns of the flexible substrate 110, the first electrode layer 120, the polymer photoelectric conversion layer 230, the second electrode layer 240, the first conductive pattern 260, and the second conductive pattern 270 can be referred to the aforesaid embodiments and are not reiterated. In the present embodiment, the first electrode layer 120 is the transparent conductive layer while the decoration layer 380 located at a side of the polymer photoelectric conversion layer 230 adjacent to the first electrode layer 120 can be a pattern layer or a releasing layer.

When the decoration layer 380 is the pattern layer, a user can see the illustrations shown by the pattern layer from a side where the flexible substrate 110 is and the ambient light can pass through the first electrode 120 to enter the polymer photoelectric conversion layer 230 from the side where the flexible substrate 110 is. In short, the disposition of the decoration layer 380 is conducive to provide specific visual effect such as specific pattern, color, metallic gloss, hologram, and the like. Herein, the flexible substrate 110 can provide the pattern layer from damages caused by ambient materials when the decoration film 300 is adhered on an object.

Generally, when the decoration layer 380 is the releasing layer, the decoration layer 380 can be usually a thin film with low surface tension which can be made of a wax, a paraffin, or silicone, or an impermeable thin film with high smoothness which can be made of an irradiation curable multi-functional acrylic, silicone acrylate, epoxy, vinyl, allyl vinyl compound, unsaturated polyester or a mixture thereof. A material of the releasing layer can be selected from a polycondensate, a copolymer, a blend, or a mixture consisting of epoxy, polyurethane, polyimide, polyamide, hexa methoxymethyl melamine-formaldehyde, urea-formaldehyde, phenol-formaldehyde, and a combination thereof. The releasing layer can provide a removable effect or a temporary adhesion effect. Therefore, the flexible substrate 110 can be removed after the adhesion layer 150 is adhered on an object so as to achieve a requirement of thin volume.

In addition, when the decoration layer 380 is the releasing layer, the flexible substrate 110 is usually removed after the adhesion layer 150 is adhered on an object. Accordingly, the decoration layer 380 can be exposed and the decoration layer 380 can optionally have a rough surface away from the adhesion layer 150 to provide a rough touching sense or a haze effect on the sense of sight. In an embodiment, the decoration layer 380 served as the releasing layer can have a rough surface by disposing a haze layer (not shown) between the substrate 110 and the decoration layer 380, wherein a plurality of particles (not shown) is distributed in the haze layer (not shown) and the surface of the decoration layer 380 can become rough due to the particles. In an embodiment, the particles can have a diameter from 0.1 μm to 30 μm, preferably 1 μm to 15 μm and a material of the particles can be silicon dioxide, calcium carbonate, calcium sulphate, barium sulphate, aluminium oxide, titanium oxide, metal powders, inorganic dye, or organic dye. In addition, the particles can be a plurality of hollow balls, non-film-forming latexes, or dispersions.

Furthermore, FIG. 4 illustrates a decoration film according to a fourth embodiment of the invention. Referring to FIG. 4, a decoration film 400 is similar to the decoration film 300 illustrated in FIG. 3. The difference between the decoration film 400 and the decoration film 300 lies in that the decoration film 400 includes two decoration layers 480 and 490 disposed between the substrate 110 and the first electrode layer 120. It is noted that the decoration layer 480 is the releasing layer and the material thereof can be referred to the above-mentioned embodiment. In addition, the decoration layer 490 can be at least one of a pattern layer, a protection layer, an easy cleaning layer, or the like. The drawing of FIG. 4 illustrates a single layer to represent the decoration layer 490, but the invention is not limited thereto. In an alternate embodiment, the decoration layer 490 can includes a plurality of layers having different functions.

When the decoration layer 490 is the protection layer, the decoration layer 490 can be an irradiation curable material layer, i.e. a thermal curing resin, an UV irradiated reaction resin or the like. Specifically, suitable raw materials for the protection layer may include, but are not limited to, radiation curable multifunctional acrylates including epoxy acrylates, polyurethane acrylates, polyester acrylates, silicone acrylates, glycidyl acrylates, epoxides, vinyl esters, diallyl phthalate, vinyl ethers and blends thereof. The protection layer may comprise a condensation polymer or copolymer, such as epoxy, polyurethane, polyamide, polyimide, melamine formaldehyde, urea formaldehyde or phenol formaldehyde. The protection layer may include a sol-gel silicate or titanium ester. In addition, when the decoration layer 490 is the protection layer, the decoration layer 490 can have a rough surface away from the first electrode layer 110, for instance.

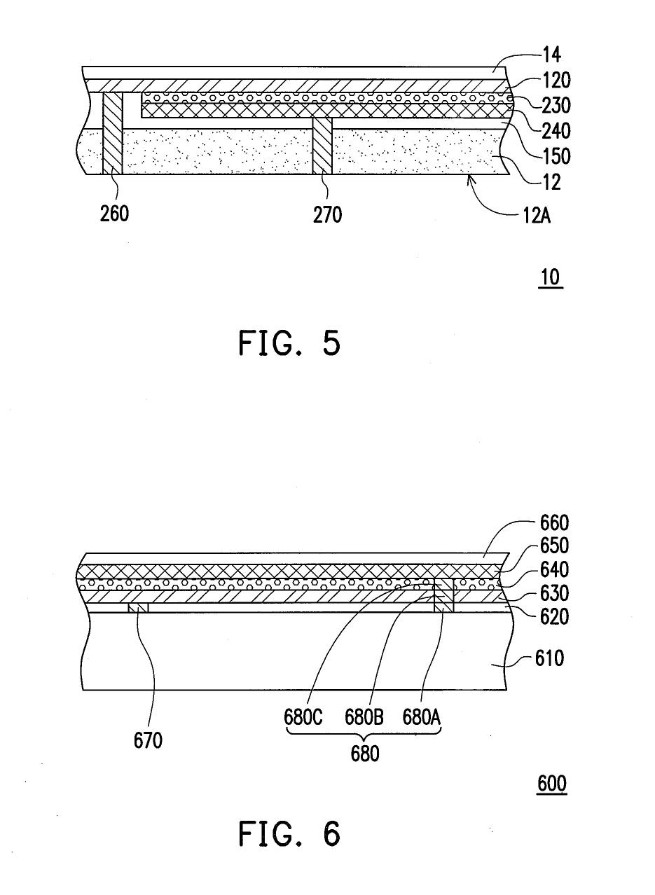

FIG. 5 illustrates a decoration device according to an embodiment of the invention. Referring to FIG. 5, a decoration device 10 includes a body 12, an outer layer 14, a first electrode layer 120, a polymer photoelectric conversion layer 230, a second electrode layer 240, an adhesion layer 150, a first conductive pattern 260, and a second conductive pattern 270. The outer layer 14 is conformally disposed on the body 12. The first electrode layer 120 is conformally disposed between the body 12 and the outer layer 14. The polymer photoelectric conversion layer 230 is conformally disposed between the body 12 and the first electrode layer 120. The second electrode layer 240 is conformally disposed between the polymer photoelectric conversion layer 230 and the body 12. The adhesion layer 150 is disposed between the second electrode layer 240 and the body 12. In the present embodiment, the first conductive pattern 260 and the second conductive pattern 270 further penetrate through the body 12 so as to be exposed at a side 12A of the body 12 away from the outer layer 14. In addition, at least the first electrode layer 120 is a transparent conductive layer to allow the ambient light to irradiate on the polymer photoelectric conversion layer 230. Specifically, a material of the body 12 includes polycarbonate (PC), polypropylene (PP), polymethylmethacrylate (PMMA), methylmethacrylate-styrene (MMA-st, MS) copolymer, MS, acrylonitrile butadiene styrene (ABS), polystyrene (PS), polyethylene terephthalate (PET), polyoxymethylene (POM) or a combination thereof.

It is noted that the decoration device 10 is made by performing an IMD process or an adhering process with one of the decoration films 200, 300, and 400 depicted in the foregoing embodiments. Accordingly, the materials and the disposition relationships of the adhesion layer 150, the second electrode layer 240, the polymer photoelectric conversion layer 230, the first electrode layer 120, the first conductive pattern 260, and the second conductive pattern 270 can be referred to the aforesaid descriptions and are not iterated here. The decoration device 10 can be a housing of an electric device. For example, the electric device can include at least one of a cell phone, a digital camera, a note book, a digital photo frame, a display, a personal digital assistant, a media player, and a global positioning system.

However, the invention is not restricted in manufacturing the decoration device 10 by using the decoration films 200, 300, and 400. In other embodiment, the decoration device 10 can be made by performing an IMD process or an adhering process with the decoration film 100 such that the second electrode layer 240 and the polymer photoelectric conversion layer 230 are respectively replaced by the second electrode layer 140 and the polymer photoelectric conversion layer 130 which are represented in a non-patterned manner. According to an embodiment of the invention, the decoration films 100, 200, 300, and 400 use the flexible substrate 110 as carrier substrate so the first electrode layer 120, the polymer photoelectric conversion layer 230, the second electrode layer 240, and the adhesion layer 150 can be conformed to the body 12.

In the present embodiment, the outer layer 14 can be one of a flexible substrate, a releasing layer, and a protection layer according to the decoration film using in the IMD process or the adhering process. For instance, when the decoration film 100 or the decoration film 200 is used in the IMD process or the adhering process for forming the decoration device 10, the outer layer 14 can be the flexible substrate 110 depicted in FIG. 1 to protect the layers between the outer layer 14 and the body 12. That is to say, the flexible substrate 100 shown in FIG. 1 and FIG. 2 is not removed after the IMD process or the adhering process. When the decoration film 300 is used for forming the decoration device 10 and the decoration film 380 is the pattern layer, the outer layer 14 can be the flexible substrate 110. That is to say, the flexible substrate 110 is not removed after the IMD process or the adhereing process and is remained on the decoration device 10.

Furthermore, when the decoration film 300 is used for forming the decoration device 10 and the decoration film 380 is the releasing layer, the outer layer 14 can be the decoration film 380. That is to say, the flexible substrate 110 is removed after the IMD process or the adhereing process and the releasing layer, i.e. the decoration layer 380, is remained on the decoration device 10. When the decoration film 400 is used for forming the decoration device 10, the outer layer 14 can be the decoration layer 490 or the decoration layer 480. Under this circumstance, the flexible substrate 110 is removed after the IMD process or the adhering process and the decoration layer 480 served as the releasing layer is optionally remained on the decoration device 10.

The outer layer 14 in the present embodiment can optionally have a rough surface away from the adhesion layer 150 to provide a rough touching sense or a haze effect on the sense of sight. In addition, a pattern layer or other decoration layers can be optionally disposed between the outer layer 14 and the first electrode layer 120 to provide additional visual effect. Certainly, another embodiment can be provided by disposing at least one function layer between the second electrode layer 240 and the adhesion layer 150 and the invention is not restricted herein.

FIG. 6 illustrates a decoration film according to a fifth embodiment of the invention. Referring to FIG. 6, a decoration film 600 includes a flexible substrate 610, an outer layer 620, a first electrode layer 630, a polymer photoelectric conversion layer 640, a second electrode layer 650, an adhesion layer 660, a first conductive pattern 670, and a second conductive pattern 680. The outer layer 620, the first electrode layer 630, the polymer photoelectric conversion layer 640, the second electrode layer 650, and the adhesion layer 660 are sequentially arranged on the flexible substrate 610 and the materials thereof can be referred to the aforesaid embodiments. The first conductive pattern 670 and the second conductive pattern 680 respectively penetrate through the outer layer 620, wherein the first conductive pattern 670 and the second conductive pattern 680 respectively contact a side of the first electrode layer 630 away from the adhesion layer 660 and a side of the second electrode layer 650 away from the adhesion layer 660.

In the present embodiment, the second conductive pattern 680 can further penetrate through the first electrode layer 630 and the polymer photoelectric conversion layer 640 while the second conductive pattern 680 is electrically isolated from the first electrode layer 630. The method for manufacturing the decoration film 600 includes sequentially forming the outer layer 620, the first electrode layer 630, the polymer photoelectric conversion layer 640, the second electrode layer 650, and the adhesion layer 660 on the flexible substrate 610 by performing a printing process. It is noted that the second conductive pattern 680 can be divided into at least three portion in the present embodiment, wherein the portion 680A can be formed simultaneously with the outer layer 620 by the same printing process, the portion 680B can be formed simultaneously with the first electrode layer 360 by the same printing process, and the portion 680C can be formed simultaneously with the polymer photoelectric conversion layer 340 by the same printing process. In addition, the first conductive pattern 670 can be also formed simultaneously with the outer layer 620 by the same printing process. That is to say, the formation of the first conductive pattern 670 and the second conductive pattern 680 is compatible to the formation of the outer layer 620, the first electrode layer 630, and the polymer photoelectric conversion layer 640 and additional manufacturing process is not required.

The outer layer 620 is, for example, a releasing layer so that the flexible substrate 610 is removed and the outer layer 620 is exposed after the decoration film 600 is adhered on an object through the adhesion layer 660. Under this circumstance, the first conductive pattern 670 and the second conductive pattern 680 can be exposed at a side of the outer layer 620 away from the adhesion layer 660 to facilitate to electrically connected to an electrical storage element and be served as a solar cell. For allowing the ambient light to irradiate on the polymer photoelectric conversion layer 640, the second electrode layer 650 can be the transparent conductive layer in the present embodiment.

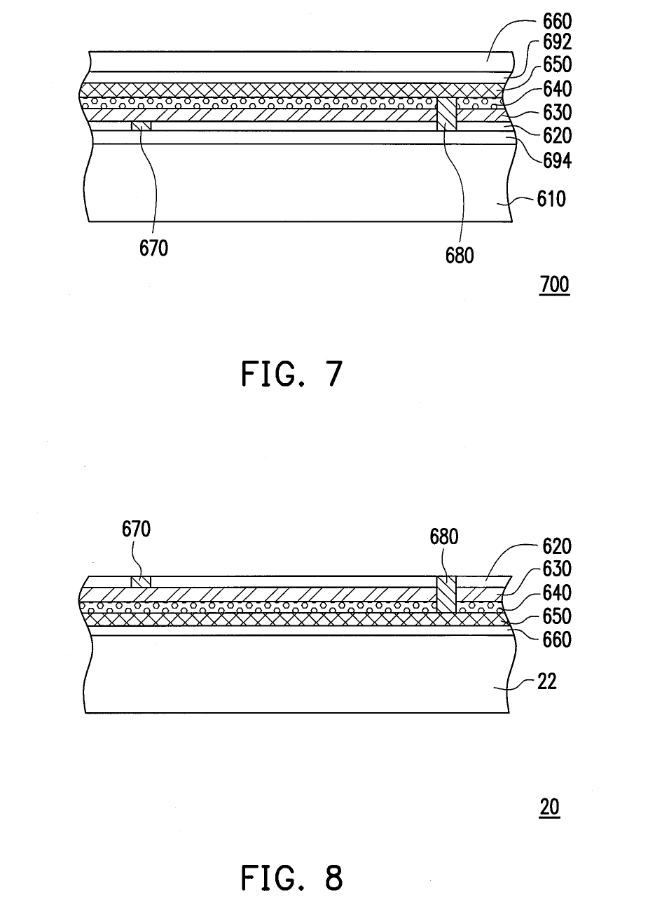

In an alternate embodiment as shown in FIG. 7 which illustrates a decoration film according to a sixth embodiment of the invention, the outer layer 620 can be a protection layer and the decoration film 700 can further includes a decoration layer 692 and a releasing layer 694. The releasing layer 694 is used for providing a removable effect or a temporary adhesion effect so that the releasing layer 694 and the flexible substrate 610 can be removed after the decoration film 700 is adhered on an object. The decoration layer 692 such as a pattern layer, a hologram layer, a color layer, or the like can be disposed between the adhesion layer 660 and flexible substrate 610 and located at a side of the polymer photoelectric conversion layer 640 adjacent to the transparent conductive layer, i.e. the second electrode layer 650, to provide specific visual effect.

FIG. 8 illustrates a decoration device according to another embodiment of the invention. Referring to FIG. 8, the decoration device 20 includes a body 22, an outer layer 620, a first electrode layer 630, a polymer photoelectric conversion layer 640, a second electrode layer 650, an adhesion layer 660, a first conductive pattern 670, and a second conductive pattern 680. The decoration device 20 can be a housing of an electric device. For example, the electric device can include at least one of a cell phone, a digital camera, a note book, a digital photo frame, a display, a personal digital assistant, a media player, and a global positioning system.

It is noted that the decoration device 20 is made by performing an IMD process or an adhering process with the decoration film 600 depicted in the foregoing embodiment, wherein the flexible substrate 610 is removed after the IMD process or the adhering process. Accordingly, the first conductive pattern 670 and the second conductive pattern 680 are exposed at a side of the outer layer 620 away from the adhesion layer 660. In an alternate embodiment, the decoration device 20 can be made by performing an IMD process or an adhering process with the decoration film 700 depicted in the foregoing embodiment, wherein the flexible substrate 610 and the releasing layer 694 are removed after the IMD process or the adhering process, and the decoration device 20 can further includes the decoration layer 692 disposed between the second electrode layer 650 and the adhesion layer 660.

In the present embodiment, the body 22 can be transparent so as to allow the ambient light to irradiate on the polymer photoelectric conversion layer 640 through the side where the body 660 is located. In addition, the first conductive pattern 670 and the second conductive pattern 680 are exposed at a side of the outer layer 620 away from the adhesion layer 660 so as to be electrically connected to an electrical storage element to store the electrical energy generated by the photoelectric conversion effect of the polymer photoelectric conversion layer 640. Accordingly, the decoration device 20 having photoelectric conversion function is achieved, which facilitates to accomplish the green energy design.

In summary, the decoration film and the decoration device according to the invention has a photoelectric conversion structure including two electrode layers and a photoelectric conversion layer therebetween. Therefore, the decoration film and the decoration device according to the invention can have the photoelectric conversion function to achieve the green energy aspiration. In addition, the photoelectric conversion layer is a polymer photoelectric conversion layer so as to be compatible to the flexibility of the decoration film and conduces to conform to the housing of the product. Accordingly, the manufacturing methods of the decoration film and the decoration device are simple while no matter the shape of the product is can the photoelectric conversion function be accomplished.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A decoration film comprising:
a flexible substrate;
a first electrode layer disposed on the flexible substrate;
a polymer photoelectric conversion layer disposed on the first electrode layer;
a second electrode layer disposed on the polymer photoelectric conversion layer, wherein the polymer photoelectric conversion layer is located between the first electrode layer and the second electrode layer and at least one of the first electrode layer and the second electrode layer is a transparent conductive layer; and
an adhesion layer disposed on the second electrode layer such that the first electrode layer, the polymer photoelectric conversion layer, and the second electrode layer being located between the adhesion layer and the flexible substrate.

2. The decoration film according to claim 1, wherein a material of the polymer photoelectric conversion layer comprises a p-type semiconductor polymer and an n-type semiconductor polymer.

3. The decoration film according to claim 2, wherein the p-type semiconductor polymer comprises at least one of polythiophene, polyfluorene, polyphenylenevinylene, a derivative of polythiophene, a derivative of polyfluorene, a derivative of polyphenylenevinylene, poly(3-hexylthiophene) (P3HT), a conjugated oligomer, and a small molecule.

4. The decoration film according to claim 3, wherein the derivative of polythiophene comprises at least one of poly(dioctyfluorene), poly[2-methoxy-5-(2-ethyl-hexyloxy)-1,4-phenylene vinylene, and a combination thereof.

5. The decoration film according to claim 3, wherein the conjugated oligomer is sexithiophene.

6. The decoration film according to claim 3, wherein the small molecule comprises at least one of pentacene, tetracene, hexabenzcoronene, phthalocyanine, porphyrines, a derivative of pentacene, a derivative of tetracene, a derivative of hexabenzcoronene, a derivative of phthalocyanine, a derivative of porphyrines, and a combination thereof.

7. The decoration film according to claim 2, wherein the n-type semiconductor polymer comprises at least one of C60, a derivative of C60, C70, a derivative of C70, carbon nanotubes, a derivative of carbon nanotubes, 3,4,9,10-perylene tetracarboxylic-bis-benzimidazole (PTCBI), N,N′-dimethyl-3,4,9,10-perylenetetracarboxylic acid diimide (Me-PTCDI), a derivative of PTCBI, a derivative of Me-PTCBI, a poly(2,5,2′,5 ′-tetrahexyloxy-7,8′-dicyano-di-p-phenylenevinylene (CN-PPV), poly(9,9′-dioctylifluorene-co-benzothiadiazole (F8BT), and a semiconductor nano particle.

8. The decoration film according to claim 7, wherein the derivative of C60 is phenyl C61-butyric acid methyl ester (PCBM).

9. The decoration film according to claim 7, wherein the carbon nanotubes comprise at least one of single wall carbon nanotubes, multi wall carbon nanotubes, and a combination thereof.

10. The decoration film according to claim 7, wherein the semiconductor nano particles comprise at least one of TiO₂ nano particles, CdSe nano particles, CdS nano particles, and a combination thereof.

11. The decoration film according to claim 1, further comprising a first conductive pattern and a second conductive pattern penetrating through the adhesion layer, wherein the first conductive pattern contacts a side of the first electrode layer away from the flexible substrate and the second conductive pattern contacts a side of the second electrode layer away from the flexible substrate.

12. The decoration film according to claim 1, further comprising a pattern layer disposed between the flexible substrate and the adhesion layer and located at a side of the polymer photoelectric conversion layer adjacent to the transparent conductive layer.

13. The decoration film according to claim 1, further comprising a releasing layer disposed between the flexible substrate and the first electrode layer.

14. The decoration film according to claim 13, further comprising a protection layer disposed between the releasing layer and the first electrode layer.

15. The decoration film according to claim 14, wherein at least one of the releasing layer and the protection layer has a rough surface away from the first electrode layer.

16. The decoration film according to claim 13, further comprising a first conductive pattern and a second conductive pattern respectively penetrating through the releasing layer, wherein the first conductive pattern and the second conductive pattern respectively contact a side of the first electrode layer away from the adhesion layer and a side of the second electrode layer away from the adhesion layer.

17. The decoration film according to claim 16, wherein the second conductive pattern further penetrates through the first electrode layer and the polymer photoelectric conversion layer while the second conductive pattern is electrically isolated from the first electrode layer.

18. A decoration device comprising
a body;
an outer layer conformally disposed on the body;
a first electrode layer conformally disposed between the body and the outer layer;
a polymer photoelectric conversion layer conformally disposed between the body and the first electrode layer;
a second electrode layer conformally disposed between the polymer photoelectric conversion layer and the body, wherein at least one of the first electrode layer and the second electrode layer is a transparent conductive layer; and
an adhesion layer disposed between the second electrode layer and the body.

19. The decoration device according to claim 18, further comprising a first conductive pattern and a second conductive pattern penetrating through the adhesion layer, wherein the first conductive pattern contacts a side of the first electrode layer away from the outer layer and the second conductive pattern contacts a side of the second electrode layer away from the outer layer.

20. The decoration device according to claim 19, wherein the first conductive pattern and the second conductive pattern further penetrate through the body and are exposed at a side of the body away from the outer layer.

21. The decoration device according to claim 18, wherein the outer layer comprises at least one of a flexible substrate, a releasing layer, and a protection layer.

22. The decoration device according to claim 18, further comprising a pattern layer disposed between the outer layer and the adhesion layer and located at a side of the polymer photoelectric conversion layer adjacent to the transparent conductive layer.

23. The decoration device according to claim 18, further comprising a first conductive pattern and a second conductive pattern penetrating through the outer layer, wherein the first conductive pattern contacts a side of the first electrode layer away from the adhesion layer and the second conductive pattern contacts a side of the second electrode layer away from the adhesion layer.

24. The decoration device according to claim 23, wherein the second conductive pattern further penetrates through the first electrode layer and the polymer photoelectric conversion layer while the second conductive pattern is electrically isolated from the first electrode layer.

25. The decoration device according to claim 18, wherein the decoration device is a housing of an electric device.

26. The decoration device according to claim 25, wherein the electric device comprises at least one of a cell phone, a digital camera, a note book, a digital photo frame, a display, a personal digital assistant, a media player, and a global positioning system.
